(19) United States
(12) Patent Application Publication
(10) Pub. No.: US 2015/0200086 A1
(43) Pub. Date: Jul. 16, 2015

(54) SEMICONDUCTOR MANUFACTURING APPARATUS AND MANUFACTURING METHOD OF SEMICONDUCTOR DEVICE

(71) Applicant: Kabushiki Kaisha Toshiba, Tokyo (JP)

(72) Inventor: Noboru Yokoyama, Kanazawa-Shi (JP)

(21) Appl. No.: 14/298,485

(22) Filed: Jun. 6, 2014

(30) Foreign Application Priority Data
Jan. 15, 2014 (JP) 2014-005065

(51) Int. Cl. H01L 21/02; F26B 3/00

(52) U.S. Cl. CPC H01L 21/02041; F26B 3/00

(57) ABSTRACT

A semiconductor manufacturing apparatus includes a chamber configured to house a semiconductor substrate therein. A vacuum part depressurizes inside of the chamber. A heater heats the semiconductor substrate. The vacuum part depressurizes the inside of the chamber in order to freeze water attached to the semiconductor substrate. The heater heats the semiconductor substrate in order to sublimate water frozen on the semiconductor substrate.

### CROSS REFERENCE TO RELATED APPLICATIONS

This application is based upon and claims the benefit of priority from the prior Japanese Patent Application No. 2014-005065, filed on Jan. 15, 2014, the entire contents of which are incorporated herein by reference.

### FIELD

The embodiments of the present invention relate to a semiconductor manufacturing apparatus and manufacturing method of a semiconductor device.

### BACKGROUND

In a semiconductor manufacturing process, spin drying or IPA (Isopropyl Alcohol) drying is frequently used as a drying technique after wet cleaning. However, as semiconductor devices have been more and more downscaled in recent years, formation of trenches having a high aspect ratio has been demanded. When trenches having a high aspect ratio are formed, water is likely to remain inside of the trenches even if the conventional spin drying or IPA drying is performed after wet cleaning. If water remains inside of the trenches, oxygen in the atmosphere, water, and silicon may react to each other and liquid glass may be generated. The liquid glass may become a cause that deteriorates the yield and property of a semiconductor device and reduces the reliability of the semiconductor device.

### BRIEF DESCRIPTION OF THE DRAWINGS

FIG. 1 is a schematic diagram showing an example of a configuration of a semiconductor manufacturing apparatus 100 according to a first embodiment;

FIGS. 2A to 2F show processes of chemical processing and cleaning processing of a semiconductor substrate W;

FIG. 3 is a diagram of water phase. The vertical axis shows the pressure and the horizontal axis shows the temperature;

FIGS. 4A to 4C are cross-sectional views showing the semiconductor substrate W processed by the semiconductor manufacturing apparatus 100 according to the first embodiment;

FIG. 5 is a schematic diagram showing an example of a configuration of a semiconductor manufacturing apparatus 200 according to a second embodiment; and

FIGS. 6A to 6E show processes of the chemical processing and the cleaning processing of the semiconductor substrate W according to the second embodiment.

### DETAILED DESCRIPTION

Embodiments of the present invention will be explained below in detail with reference to the accompanying drawings. Note that the invention is not limited thereto.

A semiconductor manufacturing apparatus includes a chamber configured to house a semiconductor substrate therein. A vacuum part depressurizes inside of the chamber. A heater heats the semiconductor substrate. The vacuum part depressurizes the inside of the chamber in order to freeze water attached to the semiconductor substrate. The heater heats the semiconductor substrate in order to sublimate water frozen on the semiconductor substrate.

### First Embodiment

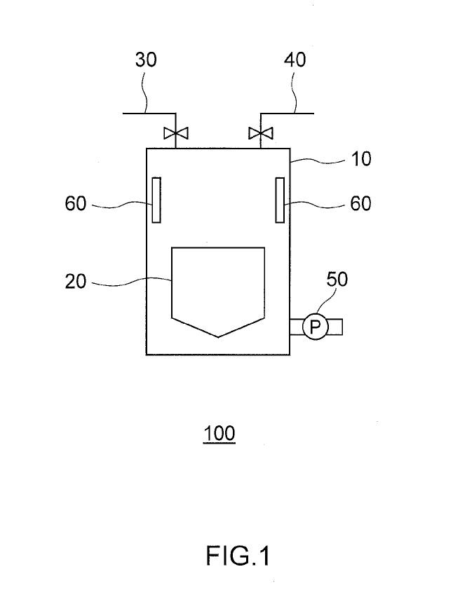

FIG. 1 is a schematic diagram showing an example of a configuration of a semiconductor manufacturing apparatus 100 according to a first embodiment. The semiconductor manufacturing apparatus 100 (hereinafter, also simply “apparatus 100”) is, for example, a wet cleaning apparatus which is an apparatus that cleans a semiconductor substrate with pure water after the semiconductor substrate is processed using a chemical.

The apparatus 100 includes a chamber 10, a processing tank 20, a nitrogen supply unit 30, an IPA supply unit 40, a vacuum pump 50, and a heater 60. The chamber 10 houses therein the processing tank 20 and the inside of the chamber 10 can be sealed and vacuumized. The processing tank 20 houses therein a semiconductor substrate and can contain a chemical or pure water to perform chemical processing or cleaning processing of the semiconductor substrate. For example, when a chemical is put into the processing tank 20 and chemical processing of the semiconductor substrate is performed, the chemical in the processing tank 20 is then replaced with pure water to perform cleaning processing of the semiconductor substrate. The processing tank 20 can be formed in a size to house therein a plurality of semiconductor substrates. In this case, the apparatus 100 can perform cleaning processing of the semiconductor substrates at the same time (batch processing). The nitrogen supply unit 30 is provided to supply nitrogen gas into the chamber 10. The IPA supply unit 40 is provided to supply IPA gas into the chamber 10. The vacuum pump 50 is provided to vacuumize the inside of the chamber 10. The heater 60 is provided to heat the semiconductor substrate after the semiconductor substrate is cleaned in the processing tank 20. Although particularly limited thereto, the heater 60 can use, for example, electric heating, laser heating, or electromagnetic induction heating to heat the semiconductor substrate. It suffices that the heater 60 can heat the semiconductor substrate in the chamber 10 and the heater 60 can be provided inside of the chamber 10 or outside of the chamber 10.

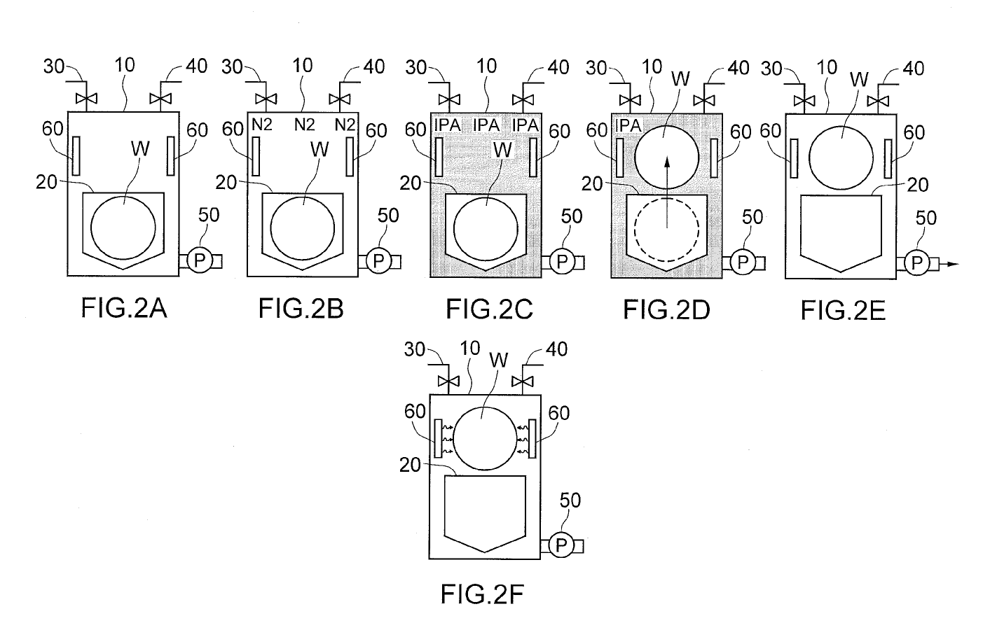

FIGS. 2A to 2F show processes of chemical processing and cleaning processing of a semiconductor substrate W. As shown in FIG. 2A, the semiconductor substrate W is first put in the processing tank 20 to perform the chemical processing and then the semiconductor substrate W is immersed in pure water. This cleans the semiconductor substrate W. At that time, the chamber 10 is filled with air. Therefore, if the semiconductor substrate W is simply pulled out after cleaning of the semiconductor substrate W, silicon of the semiconductor substrate W, water, and oxygen react to each other to form liquid glass (watermark, for example) on a surface of the semiconductor substrate W.

Therefore, as shown in FIG. 2B, the air in the chamber 10 is replaced with nitrogen in a state where the semiconductor substrate W is immersed in the pure water in the processing tank 20. At that time, a valve of the nitrogen supply unit 30 is opened to introduce nitrogen gas into the chamber 10.

A valve of the IPA supply unit 40 is then opened to introduce high-temperature IPA gas (IPA vapor) into the chamber 10 as shown in FIG. 2C. Accordingly, the chamber 10 is filled with the IPA gas.

The semiconductor substrate W is then pulled out of the processing tank 20 as shown in FIG. 2D. This exposes the surface of the semiconductor substrate W to an atmosphere of the IPA gas in the chamber 10. IPA in the chamber 10 substitutes for pure water on the surface of the semiconductor substrate W using a difference in surface tensions between IPA and water and is attached to the surface of the semiconductor substrate W. That is, IPA drying processing is performed in FIGS. 2A to 2D. However, when the semiconductor substrate W has a high-aspect-ratio trench structure, the IPA cannot substitute completely for the pure water at bottoms of the trenches and thus water may remain at the bottoms of the trenches.

The inside of the chamber 10 is then vacuumized (brought to a vacuum state) by the vacuum pump 50 as shown in FIG. 2E. When the inside of the chamber 10 is vacuumized, the temperature in the chamber 10 is lowered due to adiabatic expansion. Accordingly, the water attached to the semiconductor substrate W freezes (solidifies). The heater 60 then heats the semiconductor substrate W to sublimate the water frozen on the semiconductor substrate W as shown in FIG. 2F. That is, in the first embodiment, the semiconductor substrate W is not dried by evaporating liquid water but the semiconductor substrate W is dried by sublimating solid water into gas. The heater 60 can be a heater that applies heat directly onto the semiconductor substrate W, or any of a laser generation device that heats the semiconductor substrate W by radiating laser to the semiconductor substrate W, a device that heats the semiconductor substrate W by electromagnetic induction, and a heating device that uses an infrared lamp or a ceramic heater as a heat source.

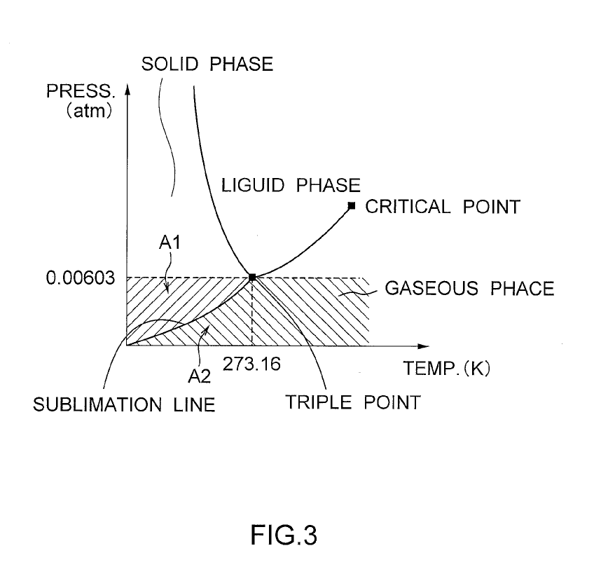

FIG. 3 is a diagram of water phase. The vertical axis shows the pressure and the horizontal axis shows the temperature. As shown in FIG. 3, water does not exist stably as a liquid phase and exists as a solid phase or a gaseous phase at pressures under the triple point. Therefore, the vacuum pump 50 reduces the pressure in the chamber 10 to a pressure equal to or lower than the water triple point. That is, the vacuum pump 50 reduces the pressure in the chamber 10 to about 0.00603 atm or lower. This freezes (solidifies) water remaining on the semiconductor substrate W due to adiabatic expansion. At that time, the state of the water is in an area denoted by A1 in FIG. 3.

When the heater 60 heats the semiconductor substrate W, the temperature of the semiconductor substrate W is caused to transition from a level lower than the water sublimation line to a level higher than the water sublimation line. That is, the heater 60 heats the semiconductor substrate W to pass the water sublimation line from the solid phase (the area A1) to the gaseous phase (an area A2). In this case, it suffices to heat the semiconductor substrate W to sublimate the frozen water from the solid phase (the area A1) to the gaseous phase (the area A2). Therefore, the temperature of the semiconductor substrate W or the temperature in the chamber 10 before and after heating can be in a range equal to or lower than 273.16 kelvins. Alternatively, the temperature of the semiconductor substrate W or the temperature in the chamber 10 before and after heating can be equal to or lower than the melting point of water at a pressure of 1 atm. Of course, the semiconductor substrate W can be heated to a temperature higher than 273.16 kelvins. In this way, the water solidified by adiabatic expansion sublimates into gas. The water changed to gas is discharged to outside of the chamber 10 via the vacuum pump 50.

The pressure in the chamber 10 is then returned to an atmospheric pressure and the semiconductor substrate W is carried out. This completes the processes of the chemical processing and the cleaning processing.

As described above, water remaining on the semiconductor substrate W is subject to adiabatic expansion and heating, thereby sublimating from the solid to the gas. This enables the water remaining on the semiconductor substrate W to be removed therefrom.

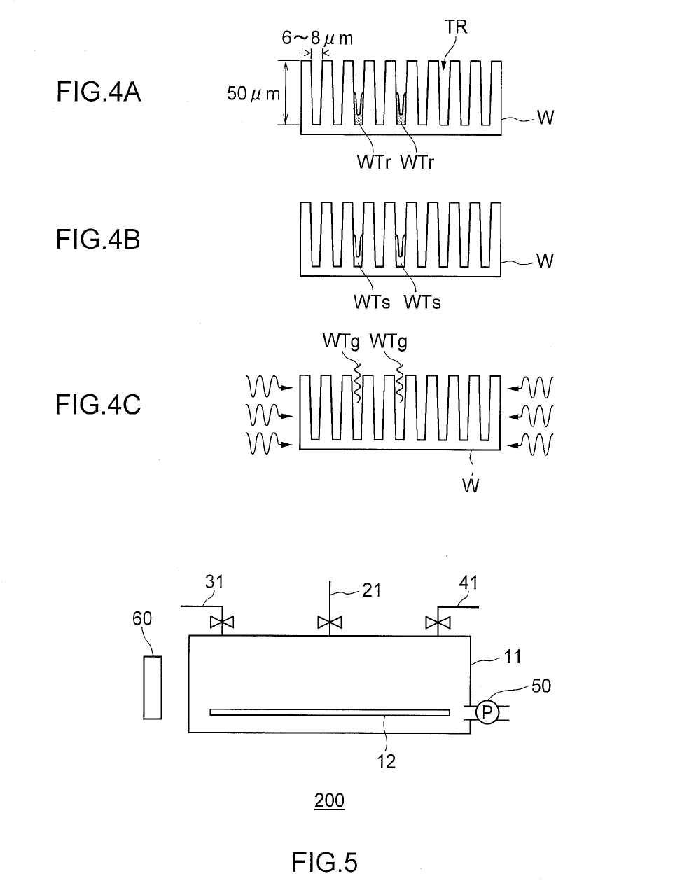

FIGS. 4A to 4C are cross-sectional views showing the semiconductor substrate W processed by the semiconductor manufacturing apparatus 100 according to the first embodiment. The semiconductor substrate W is, for example, a silicon wafer. FIG. 4A is a cross-sectional view showing the semiconductor substrate W when the semiconductor substrate W is pulled out of the processing tank 20 as shown in FIG. 2D. High-aspect-ratio trenches TR are formed on a surface of the semiconductor substrate W. An opening width of the trenches TR is, for example, about 6 to 8 micrometers and a depth of the trenches TR is, for example, 50 micrometers. Such trenches TR are used when a super-junction power MOSFET (Metal Oxide Semiconductor Field Effect Transistor) is formed, for example.

As shown in FIG. 4A, water WTr may remain at bottoms of the high-aspect-ratio trenches TR even after IPA drying. The water WTr indicates water in the liquid-phase state.

FIG. 4B is a cross-sectional view showing the semiconductor substrate W when the inside of the chamber 10 is depressurized as explained with reference to FIG. 2E. The water remaining on the surface of the semiconductor substrate W freezes due to adiabatic expansion. WTs denotes water in the solid-phase state.

FIG. 4C is a cross-sectional view showing the semiconductor substrate W during heating as explained with reference to FIG. 2F. The frozen water WTs sublimates into water WTg in the gaseous-phase state.

As described above, according to the first embodiment, the apparatus 100 freezes water remaining on the surface of the semiconductor substrate W by adiabatic expansion. The apparatus 100 then heats the frozen water to cause sublimation. The water in the solid-phase state does not react to oxygen and silicon and thus does not form liquid glass. Therefore, according to the first embodiment, by depressurizing the inside of the chamber 10, water in the liquid-phase state can be frozen to obtain water in the solid-phase state, so that contact of water in the liquid-phase state with oxygen and silicon can be suppressed as much as possible. This can suppress liquid glass such as watermark from being generated on the surface of the semiconductor substrate W. As a result, the apparatus 100 can remove water attached to the semiconductor substrate W without reducing the reliability.

If the semiconductor substrate W in a depressurized atmosphere is not heated in the IPA drying processing, the frozen water remains at the bottoms of the trenches TR. Accordingly, when the pressure in the chamber 10 is returned to the atmospheric pressure, the water remains as water in the liquid phase at the bottoms of the trenches TR and cannot be removed.

On the other hand, in the first embodiment, water on the surface of the semiconductor substrate W is frozen by depressurization and then is sublimated into gas. This removes the water from the semiconductor substrate W and there is no risk that the water changed to gas is refrozen on the semiconductor substrate W.

A timing when the semiconductor substrate W is heated can be after a timing of depressurization of the inside of the chamber 10 or the same time as the depressurization of the inside of the chamber 10. By heating the semiconductor substrate W after depressurizing the inside of the chamber 10, water can be surely frozen and then the water in the solid-phase state can be sublimated. When the semiconductor substrate W is heated at the same time as the inside of the chamber 10 is depressurized, a drying processing time can be reduced.

If the water WTr in the liquid-phase state shown in FIG. 4A is evaporatively dried, liquid glass (watermark) may be formed at the bottoms of the trenches TR. In this case, when additional etching is performed, there is a risk that the bottoms of the trenches TR are not formed into a desired shape because the watermark serves as a mask. This may be a cause that deteriorates the yield and property of a semiconductor device and reduces the reliability of the semiconductor device.

On the other hand, in the first embodiment, generation of liquid glass such as watermark on the surface of the semiconductor substrate W can be suppressed and thus the reliability of a semiconductor device can be maintained without deteriorating the yield and property of the semiconductor device.

### Second Embodiment

FIG. 5 is a schematic diagram showing an example of a configuration of a semiconductor manufacturing apparatus 200 according to a second embodiment. The semiconductor manufacturing apparatus 200 (hereinafter, also simply “apparatus 200”) is, for example, a wet cleaning apparatus which is an apparatus that cleans a semiconductor substrate with pure water after the semiconductor substrate is processed using a chemical. While the apparatus 100 is a batch processing apparatus, the apparatus 200 is a single-wafer processing apparatus.

The apparatus 200 includes a chamber 11, a stage 12, a coolant supply unit 21, a chemical supply unit 31, a pure-water supply unit 41, the vacuum pump 50, and the heater 60. The chamber 11 houses therein the stage 12, and the inside of the chamber 11 can be sealed and vacuumized. The semiconductor substrate is mounted substantially horizontally on the stage 12 to perform chemical processing and cleaning processing of the semiconductor substrate. The stage 12 can rotate the semiconductor substrate to shake off the chemical.

The coolant supply unit 21 is provided to supply a coolant onto the semiconductor substrate. The coolant is, for example, a liquid or gas having a temperature lower than the melting point of water, such as liquid nitrogen or cooled IPA. The chemical supply unit 31 is provided to supply a chemical onto the semiconductor substrate. The pure-water supply unit 41 is provided to supply pure water onto the semiconductor substrate. The coolant, the chemical, and the pure water can be remained on a surface of the semiconductor substrate using surface tensions. As necessary, the coolant, the chemical, and the pure water can be flown continuously onto the surface of the semiconductor substrate.

The vacuum pump 50 and the heater 60 can have configurations identical to those in the first embodiment.

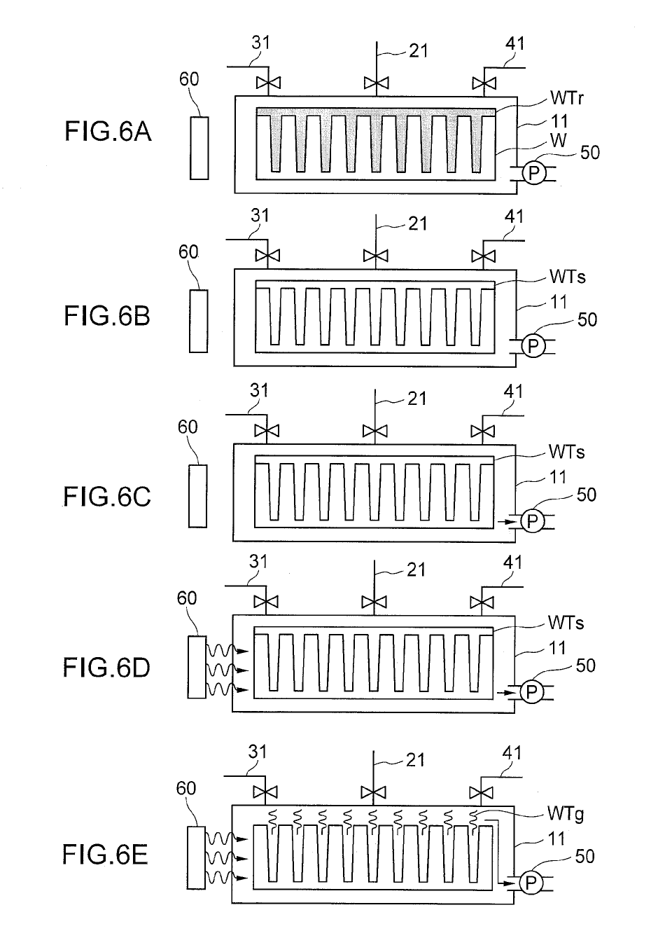

FIGS. 6A to 6E show processes of the chemical processing and the cleaning processing of the semiconductor substrate W according to the second embodiment. The semiconductor substrate W is first mounted on the stage 12 and then the chamber 11 is sealed. The chemical supply unit 31 then supplies the chemical onto the semiconductor substrate W to perform the chemical processing of the semiconductor substrate W. The pure-water supply unit 41 then supplies pure water onto the semiconductor substrate W. This cleans the semiconductor substrate W. At that time, the chamber 11 can be filled with air. This is because oxygen does not reach the surface of the semiconductor substrate W because the surface of the semiconductor substrate W is covered by pure water WTr as shown in FIG. 6A. That is, no problem occurs even when nitrogen for purging is introduced into the chamber 11.

After the semiconductor substrate W is cleaned, the coolant supply unit 21 supplies the coolant onto the semiconductor substrate W with the pure water WTr remained on the surface of the semiconductor substrate W (in a state where the surface of the semiconductor substrate W is covered by the pure water). The coolant is a liquid or gas having a temperature lower than the melting point of water as mentioned above. Therefore, by supplying the coolant onto the semiconductor substrate W, the pure water WTr on the semiconductor substrate W freezes and becomes water WTs in the solid-phase state as shown in FIG. 6B.

The vacuum pump 50 then vacuumize the inside of the chamber 11 (brings the inside of the chamber 11 to a vacuum state) as shown in FIG. 6C. When the inside of the chamber 11 is vacuumized, the temperature in the chamber 11 is lowered due to adiabatic expansion. At that time, the pressure in the chamber 11 is set to a level lower than the triple point of water.

The heater 60 then heats the semiconductor substrate W to sublimate the water frozen on the semiconductor substrate into water (vapor) WTg in the gaseous phase as shown in FIGS. 6D and 6E. That is, also in the second embodiment, the semiconductor substrate W is not dried by evaporating liquid water but the semiconductor substrate W is dried by sublimating solid water into gas as shown in FIG. 6E. The pressure in the chamber 11 and the temperature of the semiconductor substrate W are as explained with reference to FIG. 3.

The water WTg changed to gas is discharged to outside of the chamber 11 via the vacuum pump 50. The pressure in the chamber 11 is then returned to the atmospheric pressure and then the semiconductor substrate W is carried out. This completes the processes of the chemical processing and the cleaning processing.

As described above, water remaining on the semiconductor substrate W is subject to cooling, adiabatic expansion, and heating, thereby sublimating from the solid to the gas. Accordingly, the water remaining on the semiconductor substrate W can be removed.

According to the second embodiment, the apparatus 200 cools pure water that covers the surface of the semiconductor substrate W to freeze the pure water. The apparatus 200 further depressurizes and heats the frozen pure water to cause sublimation. Because the pure water covering the surface of the semiconductor substrate W is frozen as it is, oxygen does not reach the surface of the semiconductor substrate W. Therefore, the second embodiment can further suppress generation of liquid glass such as watermark on the surface of the semiconductor substrate W. The second embodiment can also achieve effects identical to those of the first embodiment.

In the second embodiment, after the pure water covering the surface of the semiconductor substrate W is frozen, the pure water is sublimated into gas. Accordingly, there is no risk that the water changed to gas is refrozen on the semiconductor substrate W.

A timing when the semiconductor substrate W is heated can be after a timing of depressurization of the inside of the chamber 11 or can be the same time as the depressurization of the chamber 11 as in the first embodiment.

The apparatus 100 according to the first embodiment can be a single-water apparatus. The apparatus 200 can be a batch apparatus.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a chamber configured to house a semiconductor substrate therein;
a vacuum part configured to depressurize inside of the chamber; and
a heater configured to heat the semiconductor substrate, wherein
the vacuum part depressurizes the inside of the chamber in order to freeze water attached to the semiconductor substrate, and
the heater heats the semiconductor substrate in order to sublimate water frozen on the semiconductor substrate.

2. The apparatus of claim 1, wherein the vacuum part depressurizes the inside of the chamber and the heater simultaneously heats the semiconductor substrate.

3. The apparatus of claim 1, wherein
the vacuum part depressurizes the inside of the chamber to a pressure equal to or lower than a triple point of water, and
the heater heats the semiconductor substrate in order to bring a temperature of the semiconductor substrate from a value lower than a water sublimation line to a value higher than the water sublimation line.

4. The apparatus of claim 2, wherein
the vacuum part depressurizes the inside of the chamber to a pressure equal to or lower than a triple point of water, and
the heater heats the semiconductor substrate in order to bring a temperature of the semiconductor substrate from a value lower than a water sublimation line to a value higher than the water sublimation line.

5. The apparatus of claim 1, wherein
the vacuum part depressurizes the inside of the chamber to a pressure equal to or lower than a triple point of water, and
the heater heats the semiconductor substrate so as to pass a water sublimation line from a solid phase to a gaseous phase.

6. The apparatus of claim 2, wherein
the vacuum part depressurizes the inside of the chamber to a pressure equal to or lower than a triple point of water, and
the heater heats the semiconductor substrate so as to pass a water sublimation line from a solid phase to a gaseous phase.

7. The apparatus of claim 1, wherein the vacuum part depressurizes the inside of the chamber to a pressure equal to or lower than 0.00603 atm.

8. The apparatus of claim 2, wherein the vacuum part depressurizes the inside of the chamber to a pressure equal to or lower than 0.00603 atm.

9. The apparatus of claim 1, further comprising an IPA supply part configured to introduce isopropyl alcohol in a gaseous phase into the chamber, wherein
after water on the semiconductor substrate is replaced with the isopropyl alcohol in the chamber, the vacuum part depressurizes the inside of the chamber in order to freeze water remaining on the semiconductor substrate, and
the heater heats the semiconductor substrate in order to sublimate water frozen on the semiconductor substrate.

10. The apparatus of claim 2, further comprising an IPA supply part configured to introduce isopropyl alcohol in a gaseous phase into the chamber, wherein
after water on the semiconductor substrate is replaced with the isopropyl alcohol in the chamber, the vacuum part depressurizes the inside of the chamber in order to freeze water remaining on the semiconductor substrate, and
the heater heats the semiconductor substrate in order to sublimate water frozen on the semiconductor substrate.

11. The apparatus of claim 1, further comprising a coolant supply part configured to supply a coolant onto the semiconductor substrate, the coolant freezing water, wherein
the vacuum part depressurizes the inside of the chamber, after the coolant is supplied onto the semiconductor substrate in the chamber in order to freeze water remaining on the semiconductor substrate, and
the heater heats the semiconductor substrate in order to sublimate water frozen on the semiconductor substrate.

12. The apparatus of claim 2, further comprising a coolant supply part configured to supply a coolant onto the semiconductor substrate, the coolant freezing water, wherein
the vacuum part depressurizes the inside of the chamber, after the coolant is supplied onto the semiconductor substrate in the chamber in order to freeze water remaining on the semiconductor substrate, and
the heater heats the semiconductor substrate in order to sublimate water frozen on the semiconductor substrate.

13. A manufacturing method of a semiconductor device, the method comprising:
depressurizing inside of a chamber in order to freeze water attached to the semiconductor substrate, the chamber being configured to house a semiconductor substrate therein; and
heating the semiconductor substrate in order to sublimate water frozen on the semiconductor substrate.

14. The method of claim 13, wherein the depressurizing of the inside of the chamber and the heating of the semiconductor substrate are simultaneously performed.

15. The method of claim 13, wherein
the inside of the chamber is depressurized to a pressure equal to or lower than a triple point of water, and
the semiconductor substrate is heated from a temperature lower than a water sublimation line to a temperature higher than the water sublimation line.

16. The method of claim 13, wherein
the inside of the chamber is depressurized to a pressure equal to or lower than a triple point of water, and
the semiconductor substrate is heated so as to pass a water sublimation line from a solid phase to a gaseous phase.

17. The method of claim 13, wherein the inside of the chamber is depressurized to a pressure equal to or lower than 0.00603 atm.

18. The method of claim 13, further comprising replacing water on the semiconductor substrate with isopropyl alcohol in the chamber, wherein
after water on the semiconductor substrate is replaced with the isopropyl alcohol, the inside of the chamber is depressurized in order to freeze water remaining on the semiconductor substrate, and
the semiconductor substrate is heated in order to sublimate water frozen on the semiconductor substrate.

19. The method of claim 13, further comprising supplying a coolant onto the semiconductor substrate in the chamber, wherein
the inside of the chamber is depressurized after supply of the coolant, and
the semiconductor substrate is heated in order to sublimate water frozen on the semiconductor substrate.
